(19) United States
(12) Patent Application Publication
(10) Pub. No.: US 2015/0361581 A1
(43) Pub. Date: Dec. 17, 2015

(54) WINDOW ASSEMBLY FOR SUBSTRATE PROCESSING SYSTEM

(71) Applicant: APPLIED MATERIALS, INC., Sant Clara, CA (US)

(72) Inventor: DAVID K. CARLSON, San Jose, CA (US)

(73) Assignee: APPLIED MATERIALS, INC., Santa Clara, CA (US)

(21) Appl. No.: 14/766,338

(22) PCT Filed: Feb. 18, 2014
(86) PCT No.: PCT/US2014/016874

§ 371 Date: Aug. 6, 2015

Related U.S. Application Data
(60) Provisional application No. 61/777,669, filed on Mar. 12, 2013.

(51) Int. Cl. C30B 25/08; C30B 29/06; C30B 25/10

(52) U.S. Cl. CPC C30B 25/08; C30B 25/105; C30B 29/06

(57) ABSTRACT

Apparatus for use in an inline substrate processing tool are provided herein. In some embodiments, a window assembly for use in an inline substrate processing tool may include a window body having an inner surface and an outer surface, the window body including a central translucent portion configured to pass radiant heat emitted from a radiant heat lamp through the central translucent portion, and a surface treated portion disposed about the central translucent portion and disposed on each of the inner and outer surfaces, the surface treated portion configured to minimize total internal reflections of the radiant heat emitted from the radiant heat lamp, and one or more molded seals disposed proximate an outer edge of the window body and on each of the inner and outer surfaces

### FIELD

Embodiments of the present invention generally relate to semiconductor processing equipment.

### BACKGROUND

Amorphous and polycrystalline solar cells are limited in their efficiency to convert light into energy. Single crystal high mobility materials are capable of much higher efficiency, but are typically much more expensive. Conventional equipment is designed for semiconductor applications with extreme requirements and with a very high cost involved. However, these systems all have high cost and are not capable of high throughput automation.

To achieve very low cost epitaxial deposition for photovoltaic applications at high throughput, the inventors believe that a radical change is required rather than simply making everything larger. For example, the inventors have observed that batch reactors are limited in throughput with high cost of materials, consumables, and automation challenges. Very high flow rates of hydrogen, nitrogen, water, and precursors are also required. Furthermore, a large amount of hazardous byproducts are generated when growing thick films.

Continuous reactors have been attempted many times for epitaxial processes but have never been production worthy nor achieved good precursor usage. The major issue is poor film quality and excessive maintenance.

On the other hand, single wafer reactors have very inefficient utilization of precursors and power (electrical) and have lower per wafer throughput. Plus single wafer reactors need complex substrate lift/rotation mechanisms. Thus, although single wafer reactors can have very high quality, low metal contamination levels, and good thickness uniformity and resistivity, the cost per wafer is very high to get these results.

Furthermore, for radiant heating in epitaxial systems, window assemblies used in these systems must withstand large temperature gradients and pressure differentials. Some epitaxial systems use circular domed windows which require expensive machining and welding to manufacture to create windows able to withstand the large temperature gradients and pressure differentials. In addition, seals must stand high temperatures and significant compressive loads. Thus, there is a need for simple, low cost windows and seals that allow hermetic sealing at elevated temperatures.

Therefore, the inventors have provided embodiments of a substrate processing tool that may provide some or all of high precursor utilization, simple automation, low cost, and a relatively simple reactor design having high throughput and process quality. In addition, the inventors have provided embodiments of a windows assembly that allows the scale-up of the window size at significantly lower cost.

### SUMMARY

Apparatus for use in an inline substrate processing tool are provided herein. In some embodiments, a window assembly for use in an inline substrate processing tool may include a window body having an inner surface and an outer surface, the window body including a central translucent portion configured to pass radiant heat emitted from a radiant heat lamp through the central translucent portion, and a surface treated portion disposed about the central translucent portion and disposed on each of the inner and outer surfaces, the surface treated portion configured to minimize total internal reflections of the radiant heat emitted from the radiant heat lamp, and one or more molded seals disposed proximate an outer edge of the window body and on each of the inner and outer surfaces of the window body.

In some embodiments, an inline substrate processing tool includes a substrate carrier having a base and pair of opposing substrate supports having respective substrate support surfaces and a plurality of modules coupled to one another in a linear arrangement including a track provided along an axial length of the plurality of modules to facilitate guiding the substrate carrier through the plurality of module, wherein at least one module of the plurality of modules comprises: a heating lamp to provide radiant heat in an inner volume of the at least one module; and a window assembly including a window body having an inner surface and an outer surface, the window body including a central translucent portion, and a surface treated portion disposed about the central translucent portion and disposed on each of the inner and outer surfaces, wherein the surface treated portion minimizes total internal reflections of the radiant heat emitted from the heating lamp, and one or more molded seals disposed proximate an outer edge of the window body and on each of the inner and outer surfaces of the window body.

Other and further embodiments of the present invention are described below.

### BRIEF DESCRIPTION OF THE DRAWINGS

Embodiments of the present invention, briefly summarized above and discussed in greater detail below, can be understood by reference to the illustrative embodiments of the invention depicted in the appended drawings. It is to be noted, however, that the appended drawings illustrate only typical embodiments of this invention and are therefore not to be considered limiting of its scope, for embodiments of the invention may admit to other equally effective embodiments.

FIG. 1 depicts an indexed inline substrate processing tool in accordance with some embodiments of the present invention;

FIG. 2A is a cross sectional side view of a window assembly for use in modules of a substrate processing tool in accordance with some embodiments of the present invention;

FIG. 2B is a cross sectional end view of a window assembly for use in modules of a substrate processing tool in accordance with some embodiments of the present invention;

FIG. 3 is a module of a substrate processing tool in accordance with some embodiments of the present invention;

FIG. 4 is a schematic top view of a gas inlet in accordance with some embodiments of the present invention; and

FIG. 5 is a substrate carrier for use in a substrate processing tool in accordance with some embodiments of the present invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Embodiments of a high volume, low cost system for epitaxial silicon deposition are provided herein. While not limiting in scope, the inventors believe that the inventive substrate processing system may be particularly advantageous for solar cell fabrication applications. In addition, embodiments of windows assemblies that allow the scale-up of the window size at significantly a lower cost for use in a high volume, low cost system for epitaxial silicon deposition are provided herein.

The inventive system may advantageously provide cost effective and simple manufacturability and an energy and cost efficient usage, as compared to conventional substrate processing tools utilized to perform multi-step substrate processes.

For example, basic design components are based on flat plates to simplify manufacturing and contain cost by using readily available materials in standard forms to keep cost down. High reliability linear lamps can be used. The specific lamps can be optimized for the specific application. The lamps may be of the type typically used in epitaxial deposition reactors. Flow fields within the system can also be optimized for each specific application to minimize waste. The design minimizes purge gas requirements and maximizes precursor utilization. Cleaning gas may be added to an exhaust system to facilitate removal of deposited material from the exhaust channels. Load and unload automation can also be separated to facilitate inline processing. Complex automation can be handled offline. Substrates are pre-loaded on carriers (susceptors) for maximum system flexibility, thereby facilitating integration to other steps. The system provides for flexibility of the system configuration. For example, multiple deposition chambers (or stations) can be incorporated for multilayer structures or higher throughput.

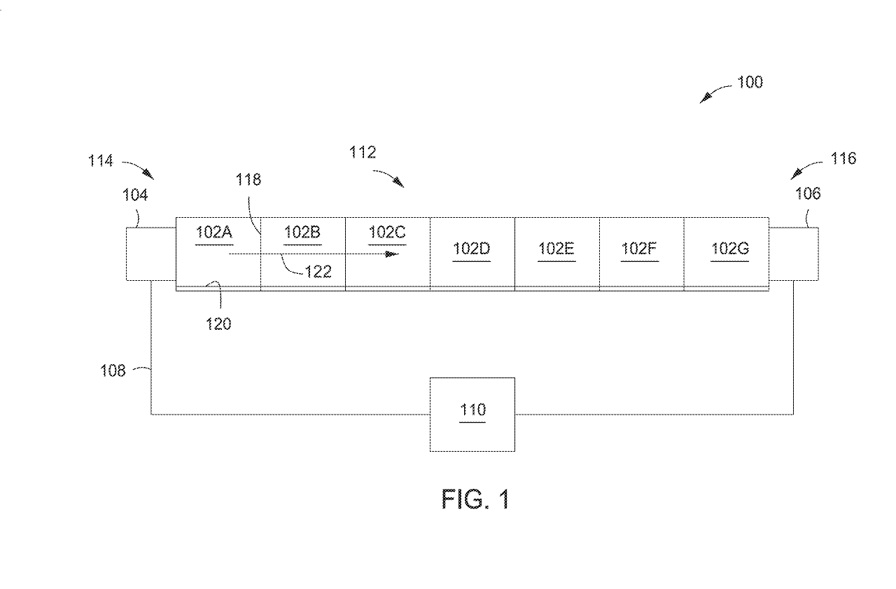

Embodiments of a high volume, low cost system for epitaxial silicon deposition may be performed using a standalone substrate processing tool, a cluster substrate processing tool or an indexed inline substrate processing tool. FIG. 1 is an indexed inline substrate processing tool 100 in accordance with some embodiments of the present invention. The indexed inline substrate processing tool 100 may generally be configured to perform any process on a substrate for a desired semiconductor application. For example, in some embodiments, the indexed inline substrate processing tool 100 may be configured to perform one or more deposition processes, for example, such as an epitaxial deposition process.

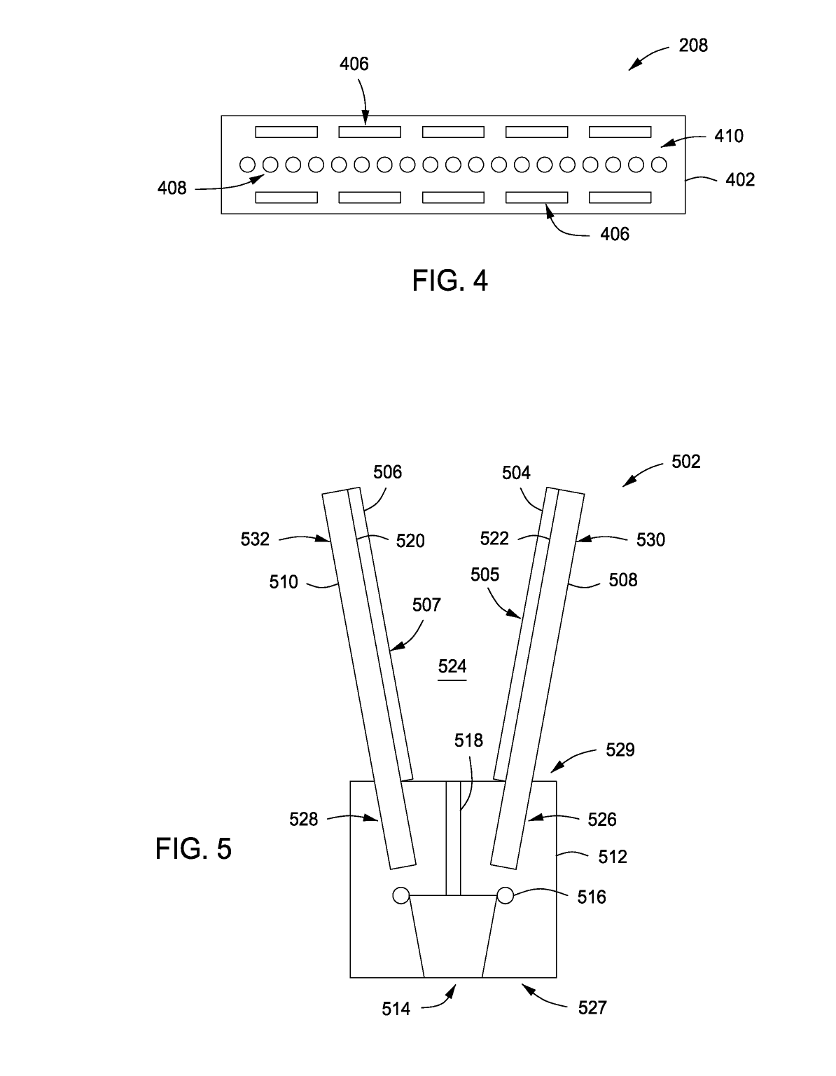

The indexed inline substrate processing tool 100 generally comprises a plurality of modules 112 (first module 102A, second module 102B, third module 102C, fourth module 102D, fifth module 102E, sixth module 102F, and seventh module 102G shown) coupled together in a linear arrangement. A substrate may move through the indexed inline substrate processing tool 100 as indicated by the arrow 122. In some embodiments, one or more substrates may be disposed on a substrate carrier, for example, such as the substrate carriers 502, 602 and 702 described below with respect to FIGS. 5-8, to facilitate movement of the one or more substrates through the indexed inline substrate processing tool 100.

Each of the plurality of modules 112 may be individually configured to perform a portion of a desired process. By utilizing each of the modules to perform only a portion of a desired process, each module of the plurality of modules 112 may be specifically configured and/or optimized to operate in a most efficient manner with respect to that portion of the process, thereby making the indexed inline substrate processing tool 100 more efficient as compared to conventionally used tools utilized to perform multi-step processes.

In addition, by performing a portion of a desired process in each module, process resources (e.g., electrical power, process gases, or the like) provided to each module may be determined by the amount of the process resource required only to complete the portion of the process that the module is configured to complete, thereby further making the inventive indexed inline substrate processing tool 100 more efficient as compared to conventionally used tools utilized to perform multi-step processes.

Furthermore, separate modules advantageously allow for depositing layers of differing dopants on one or more substrates: for example, 10 microns of p++ dopants; 10 microns of p+ dopants; 10 microns of n dopants. Meanwhile, conventional single chambers prohibit deposition of different dopants since they interfere with each other. In addition, inline linear deposition where an epitaxial layer is built up in separate chambers helps to prevent over growth or bridging of the epitaxial Silicon (Si) from the substrate over the carrier due to use of a purge gas between modules (discussed below), providing an etch effect during the transfer stage from one module to the next.

In an exemplary configuration of the indexed inline substrate processing tool 100, in some embodiments, the first module 102A may be configured to provide a purge gas to, for example, remove impurities from the substrate and/or substrate carrier and/or introduce the substrate into a suitable atmosphere for deposition. The second 102B module may be configured to preheat or perform a temperature ramp to raise a temperature of the substrate to a temperature suitable for performing the deposition. The third module 102C may be configured to perform a bake to remove volatile impurities from the substrate prior to the deposition of the materials. The fourth module 102D may be configured to deposit a desired material on the substrate. The fifth module 102E may be configured to perform a post-deposition process, for example such as an annealing process. The sixth module 102F may be configured to cool the substrate. The seventh module 102G may be configured to provide a purge gas to, for example, remove process residues from the substrate and/or substrate carrier prior to removal from the indexed inline substrate processing tool 100. In embodiments where certain processes are not needed, the module configured for that portion of the process may be omitted. For example, if no anneal is needed after deposition, the module configured for annealing (e.g., the fifth module 102E in the exemplary embodiment above) may be may be omitted or may be replaced with a module configured for a different desired process.

Some embodiments of substrate processing tool 100 include an inline “pushing mechanism” (now shown) or other mechanism that is able to serially transfer the abutting substrate carriers through modules 102A-102G. For example, indexed transport can use a pneumatic plunger-type push mechanism to drive carrier modules forward through the in-line reactor.

Some or all of the plurality of modules may be isolated or shielded from adjacent modules, for example by a barrier 118, to facilitate maintaining an isolated processing volume with respect to other modules in the indexed inline substrate processing tool 100. For example, in some embodiments, the barrier 118 may be a gas curtain, such as of air or of an inert gas, provided between adjacent modules to isolate or substantially isolate the modules from each other. In some embodiments, gas curtains can be provided along all four vertical walls of each module, or of desired modules (such as deposition or doping modules), to limit unwanted cross-contamination or deposition in undesired locations of the module or carriers. Such isolation also prevents contaminants such as carbon or moisture from reaching the reaction zone/substrates.

In some embodiments, the barrier 118 may be a gate or door that can open to allow the substrate carrier to move from one module to the next, and can be closed to isolate the module. In some embodiments, the indexed inline substrate processing tool 100 may include both gas curtains and gates, for example, using gas curtains to separate some modules and gates to separate other modules, and/or using gas curtains and gates to separate some modules. Once the push mechanism delivers the substrate carriers to a desired position in each chamber, a door/gate assembly (and chamber liner elements) forms a seal around the substrate carrier to form an enclosed region within each chamber. As the door mechanism is opening or closing a gas flow (i.e., gas purge, or gas curtain) is provided between each door and its adjacent carriers to prevent cross-contamination between chambers. The provided gas flow is received by one or more exhaust ports that are disposed in the bottom of the processing tool 100.

In some embodiments, isolation is provided by purge gas curtains using nitrogen or argon gas depending on the location of the gas curtain. For example, the gas curtain in the hotter processing regions would be formed using argon gas. The gas curtains in colder regions near the gates, away from the hotter processing regions, could by nitrogen to minimize cost of operation. The nitrogen gas curtains can only be used in cold, inert sections of each module.

In some embodiments, a load module 104 may be disposed at a first end 114 of the indexed inline substrate processing tool 100 and an unload module 106 may be disposed at a second end 116 of the indexed inline substrate processing tool 100. When present, the load module 104 and unload module 106 may facilitate providing a substrate to, and removing a substrate from, the indexed inline substrate processing tool 100, respectively. In some embodiments, the load module 104 and the unload module 106 may provide vacuum pump down and back to atmospheric pressure functions to facilitate transfer of substrates from atmospheric conditions outside of the indexed inline substrate processing tool 100 to conditions within the indexed inline substrate processing tool 100 (which may include vacuum pressures). In some embodiments, one or more substrate carrier transfer robots may be utilized to provide and remove the substrate carrier from the load module 104 and the unload module 106, thereby providing an automated loading and unloading of the substrate carrier to and from the indexed inline substrate processing tool 100.

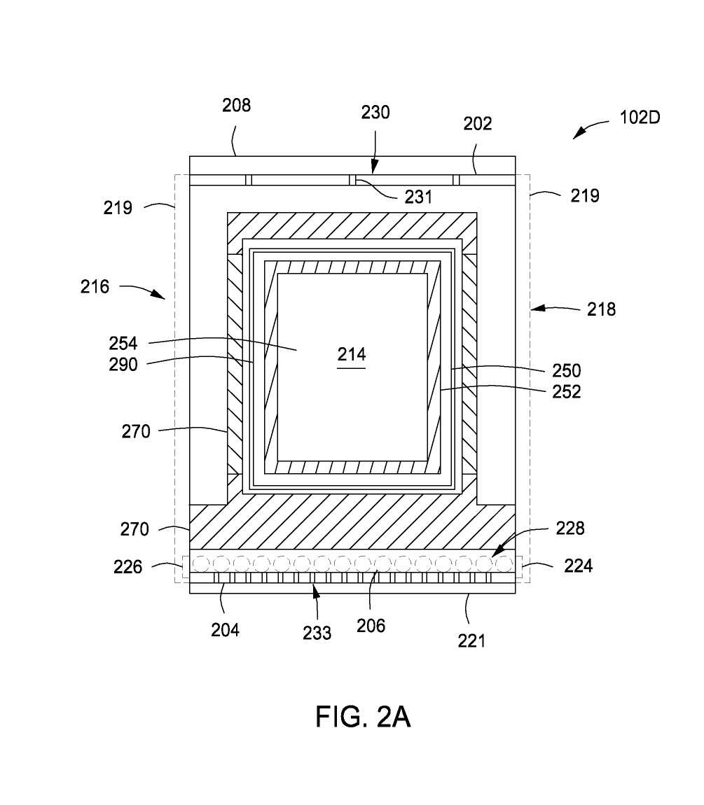

In some embodiments, a track 120 may be provided along the axial length of the indexed inline substrate processing tool 100 to facilitate guiding the substrate carrier through the indexed inline substrate processing tool 100. The track 120 may be provided along a floor of a facility or other base surface upon which the indexed inline substrate processing tool 100 is mounted. In such embodiments, each module may be configured to be assembled such that the track 120 may be positioned along an exposed bottom portion of the module to facilitate moving the substrate carrier along the track 120 and through each respective module. Alternatively, the track 120 may be mounted to a bottom surface of the modules once assembly in a linear array. Alternatively, portions of the track 120 may be mounted to a bottom surface of each individual module such that the complete track 120 is formed after assembly of all of the modules in a linear array. In some embodiments, the track 120 may include wheels, ball bearings or other types of rollers to facilitate low friction movement of the substrate carrier along the track 120. In some embodiments, the track 120 may be fabricated from or may be coated with a low friction material, such as described below with respect to FIG. 2, to facilitate low friction movement of the substrate carrier along the track 120.

In some embodiments, a cleaning module 110 may be disposed between the load module 100 and the unload module 106. When present, the cleaning module 110 may clean and/or prepare the substrate carrier to receive another one or more substrates for a subsequent run through the indexed inline substrate processing tool 100 (as indicated by the return path arrow 108). As such, the substrate carriers may be re-used multiple times.

FIG. 2A depicts a cross sectional view of an exemplary configuration of a module, such as module 102D, that may be used as one or more of the modules of the plurality of modules 112 described above, and in some embodiments, as a module configured for the deposition of materials on a substrate. Although generally discussed below in terms of a specific module (102E), the below discussion generally applies to all modules with the exception of components and/or configurations only specifically required for a deposition process.

Referring to FIG. 2, in some embodiments, the module 102D generally comprises an enclosure 202. The enclosure 202 may be fabricated from any material suitable for semiconductor processing, for example, a metal such as aluminum, stainless steel, or the like. The enclosure 202 may have any dimensions suitable to accommodate a substrate carrier (e.g., substrate carrier 502 described below) configured to carry one or more substrates of a given size as well as to facilitate a desired flow rate and profile. For example in some embodiments, the enclosure may have a height and length of about 24 inches or about 36 inches and a depth of about 6 inches.

In some embodiments, the enclosure 202 may be assembled by coupling a plurality of plates together to form the enclosure 202. Each enclosure 202 may be configured to form a particular module (e.g., module 102D) that is capable of performing a desired portion of a process. By assembling the enclosure 202 in such a manner, the enclosure 202 may be produced in multiple quantities for multiple applications via a simple and cost effective process.

A lower surface 206 of the enclosure supports the substrate carrier and provides a path for the substrate carrier to move linearly through the module 102D to an adjacent module of the plurality of modules. In some embodiments, the lower surface 206 may be configured as the track 120. In some embodiments, the lower surface 206 may have the track 120, or a portion thereof, coupled to the lower surface 206. In some embodiments, the lower surface 206, or the track 120, may comprise a coating, for example, a dry lubricant such as a nickel alloy (NiAI) containing coating, to facilitate movement of the substrate carrier through the module 102D. Alternatively, or in combination, in some embodiments, a plurality of rollers (shown in phantom at 228) may be disposed above the lower surface 206 to facilitate movement of the substrate carrier through the module 102D. In such embodiments, the plurality of rollers 228 may be fabricated from any material that is non-reactive to the process environment, for example, such as quartz (SiO₂).

In some embodiments, a barrier 219 may be disposed proximate the first end 216 and/or second end 218 of the enclosure 202 (e.g., to form the barrier 118 as shown in FIG. 1). When present, the barrier 219 isolates each module of the plurality of modules from an adjacent module to prevent cross contamination or mixing of environments between modules. In some embodiments, the barrier 219 may be a stream of gas, for example a purge gas, provided by a gas inlet (e.g., such as the gas inlet 208) disposed above the module 102D. Alternatively, or in combination, in some embodiments, the barrier 219 may be a movable gate. The gate provides additional isolation for certain processes, for example, during the deposition part of the sequence. In some embodiments, one or more notches (two notches 224, 226 shown) may be formed in the gate to facilitate securing the substrate carrier in a desired position within the module 102D and/or to form a seal between the substrate carrier and the barrier 219 during processing.

In some embodiments, the gate may be fabricated from a metal, such as aluminum, polished stainless steel, or the like. In other embodiments, the gates in hotter regions of the processing system can be made out of quartz to withstand the high temperatures.

In some embodiments, the module 102D may include a gas inlet 208 disposed proximate a top 230 of the enclosure 202 to provide one or more gases into the enclosure 202 via through holes 231 formed in the enclosure 202. The gas inlet 208 may be configured in any manner suitable to provide a desired process gas flow to the enclosure 202. Gas injection may be provided between the two substrate carriers to contain the process gases in the reaction zone between the two substrate carriers, and/or purge gases between the substrate carriers and the module walls.

In some embodiments, the module 102D may comprise an exhaust 221 coupled to a portion of the enclosure 202 opposite the gas inlet 208 (e.g. the bottom 204) to facilitate the removal gases from the enclosure 202 via passageways 233 formed in the bottom 204 of the enclosure 202.

In some embodiments, the module 102D may comprise one or more windows disposed in one or more sides of the enclosure, for example such, as the window assembly 214 disposed in the enclosure 202, as shown in FIGS. 2A and 2B. The window assembly 214 allows radiant heat 268 (e.g., IR transmission) to be provided into the enclosure 202 from, for example, a radiant heat lamp disposed on a side of the window assembly 214 opposite the interior of the enclosure 202. In some embodiments, the window assembly 214 includes a window body 290 that may be fabricated from any material suitable to allow the passage of radiant heat through a portion of the window assembly 214 while resisting degradation when exposed to the processing environment within the enclosure 202. For example, in some embodiments, the window body 290 may be fabricated from clear, flat quartz (SiO₂). In some embodiments, the quartz selected has a low water content which maximizes IR transmission through a portion of the window body 290. Other suitable translucent materials may also be used. In some embodiments, the window body 290 may be about 6-8 mm thick, although other thickness may be used depending on processing environment requirements.

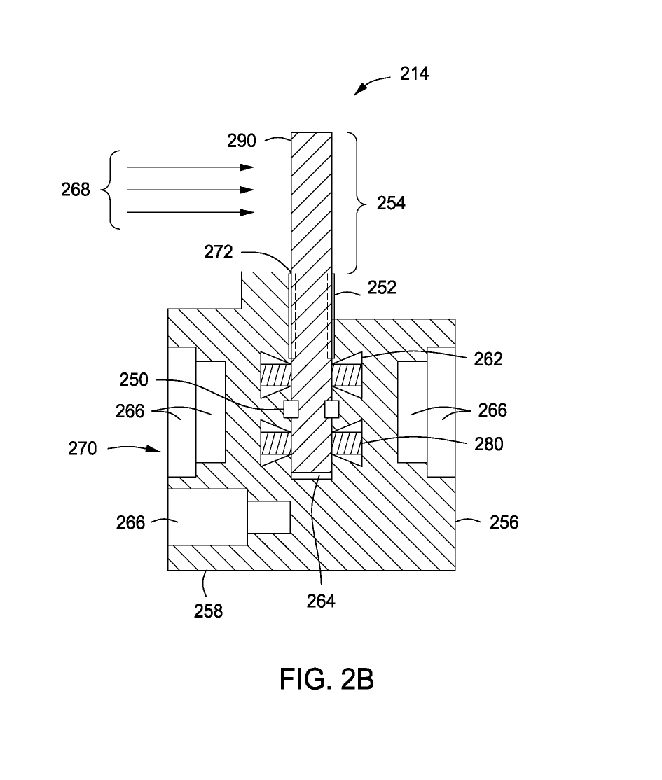

In some embodiments, the window body 290 may include a central translucent portion 254 that allows radiant heat 268 (e.g., IR transmission) to be provided into the enclosure 202. In some embodiments, all sharp edges of the central translucent portion 254 are machined surfaces and are rounded and Fire-Polished. In some embodiments, the window body 290 further includes a bead blasted portion 252 formed on both surfaces of the window (i.e., an inner surface and an outer surface) to minimize Total Internal Reflections (TIR) of the radiant heat 268 emitted from the radiant heat lamp (discussed below with respect to FIG. 3 in more detail). By minimizing the TIR of the radiant heat 268, the bead blasted portion 252 advantageously minimizes thermal conductivity and light piping at the seal surfaces. In addition, the use of bead blasting to form the bead blasted portion 252 minimizes the amount of machining required to fabricate the window assembly 214 and eliminates the need to weld opaque material to a translucent material as does with convention window assemblies. This advantageously lowers manufacturing cost and produces less manufacturing variability. In some embodiments, bead blasting of the window body 290 is done with clean virgin material to minimize contamination, and performed in a manner that does not degrade the structural integrity of the window body 290. In some embodiments, the bead blasted portion 252 may have a width of about 1 inch to about 4 inches thick and be disposed proximate the periphery of the window assembly 214 as shown in FIG. 2A.

In some embodiments, the window assembly 214 may include a differential vacuum seal 250 that includes a dual seal with a differentially pumped vacuum channel. The differential vacuum seal 250 advantageously addresses issues with seal permeability at high temperatures (e.g., between about 600° F. to about 800° F.) and provides continuous real time monitoring of seal integrity by monitoring base pressure within the differential seal pumped area. In some embodiments, the differential vacuum seal 250 is disposed between molded seals 280 that serve as contamination barriers and as load bearing seals. The molded seals 280 may be a molded Fluorocarbon or Polytetrafluoroethylene (PTFE) seal. In some embodiments, the molded seals 280 may be rectangular gaskets, circular o-rings, or another type of seal.

In some embodiments, the window assembly 214 may be retained in module 102 by a retention structure 270. In some embodiments, the retention structure 270 may be a frame that supports the window assembly 214 on four sides. In some embodiments, the retention structure 270 may include a rigidly mounted portion 258 that is rigidly mounted to the module 102, and a retention portion 256 coupled to the rigidly mounted portion 258 to retain the window assembly 214 within the module 102 as shown in FIG. 2B. In some embodiments, the retention portion 256 may be bolted, welded, clamped, or the like, to the rigidly mounted portion 258. In some embodiments, the retention structure 270 may be formed from stainless steel, aluminum, or other suitable material able to withstand the processing environment of the module 102 it is disposed in. FIG. 2B depicts details of a lower portion of the retention structure 270 including the retention portion 256 coupled to the rigidly mounted portion 258. However, it should be understood by those skilled in the art that at least some of the features of the lower portion of the retention structure 270 described with respect to FIG. 2B may also apply to an upper portion of the retention structure 270.

The retention structure 270 includes a groove 272 formed by coupling the retention portion 256 to the rigidly mounted portion 258. The window body 290 is disposed in grove 272, thereby supporting the window body 290. In some embodiments, a gap 264 may be formed at the bottom of the groove 272 once the window body 290 is disposed in the groove 272. The retention structure 270 includes one or more recesses 262 that contain molded seals 280. The retention structure 270 may also include a plurality of water cooling channels 266 the cool the window assembly as it is heated by the radiant heat lamps discussed below.

Referring to FIG. 3, in some embodiments, the module 102D may include one or more heating lamps (two heating lamps 302, 304 shown) coupled to the sides 306, 308 of the enclosure 202. The heating lamps 302, 304 provide radiant heat into to enclosure 202 via the windows 214. The heating lamps 302, 304 may be any type of heating lamp suitable to provide sufficient radiant heat into the enclosure to perform a desired portion of a process within the module 102D. For example, in some embodiments, the heating lamps 302, 304 may be linear lamps or zoned linear lamps capable of providing radiant heat at a wavelength of about 0.9 microns, or in some embodiments, about 2 microns. The wavelengths used for lamps in various modules may be selected based upon the desired application. For example, the wavelength may be selected to provide a desired filament temperature. Low wavelength bulbs are less expensive, use less power, and can be used for preheating. Longer wavelength bulbs provide high power to facilitate providing higher process temperatures, for example, for deposition processes.

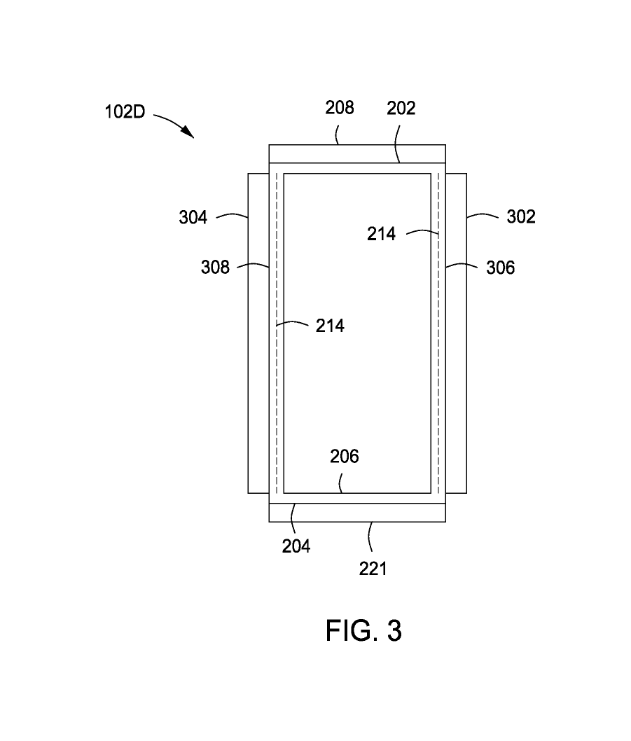

In some embodiments, Infrared (IR) lamps may be provided in one or more zones to provide heat energy to the substrate carriers and ultimately to the substrates. Portions of the chamber where no deposition is desired, such as the windows, may be fabricated of materials that will not absorb IR light energy and heat up. Such thermal management keeps deposition substantially contained to desired areas. The one or more zones of IR lamps, for example in horizontal bands from top to bottom of sides of the module, facilitate controlling vertical temperature gradients to compensate for depletion effects or other vertical non-uniformities of deposition or other processing. In some embodiments, temperature can also be modulated over time as well as between zones. This type of granular temperature control, in addition to the gas injection modulation described above with respect to FIG. 4, or combinations thereof, can facilitate control of substrate processing results from top to bottom of the substrates as well as lateral edge to edge (for example, a thickness of a deposited film or uniformity of dopant concentration and/or depth).

FIG. 4 is a schematic top view of a gas inlet in accordance with some embodiments of the present invention. In some embodiments, the gas inlet 208 may comprise a gas distribution plate 402 having a plurality of gas orifices 410. The gas orifices 410 may be configured to provide a desired flow of process gases into the enclosure 202. For example, in some embodiments, the gas orifices 410 may comprise a plurality of inner gas holes 408 and a plurality of outer gas slots 406, such as shown in FIGS. 4. In such embodiments, the inner gas holes 408 may provide a high velocity jet flow of process gases to a central area of the enclosure 202 to facilitate a process. In some embodiments, outer gas slots 406 may provide a lower velocity laminar flow of process gases over substrates disposed in the substrate carriers.

FIG. 5 depicts at least one exemplary embodiment of a substrate carrier 502 that may be used with embodiments of the present invention described herein. The substrate carrier 502 may support two or more substrates and carry the two or more substrates through the indexed inline substrate processing tool 100 or to a cluster substrate processing tool (not shown). In some embodiments, the substrate carrier 502 may generally include a base 512 and a pair of opposing substrate supports 508, 510. One or more substrates, (substrate 504, 506 shown in FIG. 5) may be disposed on each of the substrate supports 508, 510 for processing. In some embodiments, the substrate supports 508, 510 are secured on substrate carrier 502 and may be held at an acute angle with respect to each other, with the substrates facing each other and defining a reaction zone therebetween. For example, in some embodiments the substrate supports 508, 510 are held at an angle of about between 2 degrees and 10 degrees from vertical.

The base 512 may be fabricated from any material suitable to support the substrate supports 508, 510 during processing, for example such as graphite. In some embodiments, a first slot 526 and a second slot 528 may be formed in the base 512 to allow for the substrate supports 508, 510 to be at least partially disposed within the first slot 526 and second slot 528 to retain the substrate supports 508, 510 in a desired position for processing. In some embodiments, the substrate supports 508, 510 are generally slightly angled outwardly such that the substrate supporting surfaces generally oppose each other and are arranged in a “v” shape. In some embodiments, the base 512 is fabricated from an insulating material and may be either clear or opaque quartz or a combination of clear and opaque quartz for temperature management.

A channel 514 is disposed in a bottom surface 527 of the base 512 and an opening 518 is disposed through the base 512 from a top surface 529 of the base 512 to the channel 514 to form a path for one or more gases to flow through the base 512. For example, when the substrate carrier 502 is disposed in a module, such as the module 102D described above, the opening 518 and channel 514 facilitates a flow of gas from a gas inlet (e.g., gas inlet 208 described above) to an exhaust of the module (e.g., exhaust 221 of module 102D described above). The carriage may be fabricated from quartz with the exhaust and cleaning channels machined into the quartz or a metal base disposed below the quartz. A baffle may be provided to facilitate evening out the flow through the base 512.

In some embodiments, the base 512 may include a conduit 516 disposed within the base 512 and circumscribing the channel 514. The conduit 516 may have one or more openings formed along the length of the conduit 516 to fluidly couple the conduit 516 to the channel 514 to allow a flow of gas from the conduit 516 to the channel 514. In some embodiments, while the substrate carrier 502 is disposed in a module, a cleaning gas may be provided to the conduit 516 and channel 514 to facilitate removal of deposited material from the channel 514. The cleaning gases may be provided proximate one or more exhausts to prevent deposition of process byproducts within the exhaust, thereby reducing downtime necessary for cleaning maintenance. The cleaning gas may be any gas suitable to remove a particular material from the module. For example, in some embodiments the cleaning gas may comprise one more chlorine containing gases, such as hydrogen chloride (HCl), chlorine gas (Cl₂), or the like. Alternatively, in some embodiments, an inert gas may be provided to the conduit 516 and channel 514 to minimize deposition of material on the channel 514 by forming a barrier between the exhaust gases flowing through the channel and the surfaces of the channel.

The substrate supports 508, 510 may be fabricated from any material suitable to support a substrate 504, 506 during processing. For example, in some embodiments, the substrate supports 508, 510 may be fabricated from graphite. In such embodiments, the graphite may be coated, for example with silicon carbide (SiC), to provide resistance to degradation and/or to minimize substrate contamination.

The opposing substrate supports 508, 510 comprise respective substrate support surfaces 520, 522 that extend upwardly and outwardly from the base 512. Thus, when substrates 504, 506 are disposed on the substrate supports 508, 510, a top surface 505, 507 of each of the substrates 504, 506 face one another. Facing the substrates 504, 506 toward one another during processing advantageously creates a radiant cavity between the substrates (e.g. in the area 524 between the substrate supports 508, 510) that provides an equal and symmetrical amount of heat to both substrates 504, 506, thus promoting process uniformity between the substrates 504, 506.

In some embodiments, during processing, process gases are provided to the area 524 between the substrate supports 508, 510 while a heat source disposed proximate a back side 530, 532 of the substrate supports 508, 510 (e.g., the heating lamps 302, 304 described above) provides heat to the substrates 504, 506. Providing the process gases to the area 524 between the substrate supports 508, 510 advantageously reduces exposure of the process gases to interior components of the modules, thus reducing material deposition on cold spots within the modules (e.g., the walls of the modules, windows, or the like) as compared to conventional processing systems that provide process gases between a heat source and substrate support. In addition, the inventor has observed that by heating the substrates 504, 506 via the back side 530, 532 of the substrate supports 508, 510 any impurities within the module will deposit on the back side 530, 532 of the substrate supports 508, 510 and not the substrates 504, 506, thereby advantageously allowing for the deposition of materials having high purity and low particle count atop the substrates 504, 506.

In operation of the indexed inline substrate processing tool 100 as described in the above figures, the substrate carrier 502 having a first set of substrates disposed in the substrate carrier 502 (e.g. substrates 504, 506) is provided to a first module (e.g. first module 102A). When present, a barrier (e.g., barrier 118 or barrier 219) on the first side and/or the second side of the first module may be closed or turned on to facilitate isolating the first module. A first portion of a process (e.g., a purge step of a deposition process) may then be performed on the first set of substrates. After the first portion of the process is complete, a second substrate carrier having a second set of substrates disposed in a second substrate carrier is provided to the first module. As the second substrate carrier is provided to the first module, the second substrate carrier pushes the first carrier to the second module (e.g., the second module 102B). The first portion of the process is then performed on the second set of substrates in the first module while a second portion of the process is performed on the first set of substrates in the second module. The addition of subsequent substrate carriers repeats to provide each substrate carrier to a fixed position (i.e., within a desired module), thus providing a mechanical indexing of the substrate carriers. As the process is completed in the substrate carriers may be removed from the indexed inline substrate processing tool 100 via an unload module (e.g., unload module 106).

While the foregoing is directed to embodiments of the present invention, other and further embodiments of the invention may be devised without departing from the basic scope thereof.

1. A window assembly for use in an inline substrate processing tool, the window assembly comprising:
a window body having an inner surface and an outer surface, the window body including:
a central translucent portion configured to pass radiant heat emitted from a radiant heat lamp through the central translucent portion; and
a surface treated portion disposed about the central translucent portion and disposed on each of the inner and outer surfaces, the surface treated portion configured to minimize total internal reflections of the radiant heat emitted from the radiant heat lamp; and
one or more molded seals disposed proximate an outer edge of the window body and on each of the inner and outer surfaces of the window body.

2. The window assembly of claim 1, further comprising:
a differential vacuum seal disposed proximate the one or more molded seals, the differential vacuum seal including a dual seal with a vacuum channel.

3. The window assembly of claim 2, wherein the differential vacuum seal is disposed between two molded seals.

4. The window assembly of claim 2, wherein the differential vacuum seal allows for continuous real time monitoring of seal integrity by monitoring base pressure within a pumped area of the differential vacuum seal.

5. The window assembly of claim 1, wherein the central translucent portion is fabricated from a material that is translucent to IR radiation.

6. The window assembly of claim 1, wherein the central translucent portion is fabricated from clear, flat quartz (SiO₂).

7. The window assembly of claim 1, wherein the surface treated portion is bead blasted on an inner and outer surface of the surface treated portion.

8. The window assembly of claim 1, wherein a width of the surface treated portion is about 1 inch to about 4 inches and is disposed proximate a periphery of the window assembly.

9. The window assembly of claim 1, wherein the one or more molded seals are a molded Fluorocarbon or Polytetrafluoroethylene (PTFE) seals.

10. The window assembly of claim 1, wherein the one or more molded seals are one of a rectangular gasket or circular O-ring.

11. The window assembly of claim 1, wherein the window body is about 6 mm to about 8 mm thick.

12. The window assembly of claim 1, wherein the surface treated portion minimizes thermal conductivity and light piping at surfaces of the one or more seals.

13. An inline substrate processing tool, comprising:
a substrate carrier having a base and pair of opposing substrate supports having respective substrate support surfaces; and
a plurality of modules coupled to one another in a linear arrangement including a track provided along an axial length of the plurality of modules to facilitate guiding the substrate carrier through the plurality of module, wherein at least one module of the plurality of modules comprises:
a heating lamp to provide radiant heat in an inner volume of the at least one module; and
a window assembly including:
a window body having an inner surface and an outer surface, the window body including a central translucent portion, and a surface treated portion disposed about the central translucent portion and disposed on each of the inner and outer surfaces, wherein the surface treated portion minimizes total internal reflections of the radiant heat emitted from the heating lamp; and
one or more molded seals disposed proximate an outer edge of the window body and on each of the inner and outer surfaces of the window body.

14. The inline substrate processing tool of claim 13, wherein the window assembly further comprises:
a differential vacuum seal including a dual seal with a vacuum channel.

15. The inline substrate processing tool of claim 14, wherein the differential vacuum seal is disposed between two molded seals.

16. The inline substrate processing tool of claim 14, wherein the differential vacuum seal allows for continuous real time monitoring of seal integrity by monitoring base pressure within a pumped area of the differential vacuum seal.

17. The inline substrate processing tool of claim 13, wherein the central translucent portion is fabricated from a material that is translucent to IR radiation.

18. The inline substrate processing tool of claim 13, wherein the central translucent portion is fabricated from clear, flat quartz (SiO₂).

19. The inline substrate processing tool of claim 13, wherein the surface treated portion is bead blasted on an inner and outer surface of the surface treated portion.

20. The inline substrate processing tool of claim 13, wherein a width of the surface treated portion is about 1 inch to about 4 inches and is disposed proximate a periphery of the window assembly.
